(19) United States
(12) Patent Application Publication
(10) Pub. No.: US 2007/0042509 A1
(43) Pub. Date: Feb. 22, 2007

(54) Detecting endpoint using luminescence in the fabrication of a microelectronics device

(75) Inventors: Jingqiu Chen, Dallas, TX (US); Yanghua He, Richardson, TX (US); Neal T. Murphy, Richardson, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/206,391

(22) Filed: Aug. 18, 2005

(51) Int. Cl. H01L 21/00

(52) U.S. Cl. 438/8

(57) ABSTRACT

The present invention provides a method of detecting an endpoint of the removal of a material from a microelectronics substrate. This embodiment includes removing at least a portion of an overlying material 210 located over a luminescent layer 215 that is located over a microelectronics substrate 220 and using luminescence emission 240 to determine an endpoint of the removal of the overlying material 210.

### TECHNICAL FIELD OF THE INVENTION

The present invention is directed in general to a method for manufacturing a microelectronics device, and more specifically, to a method of detecting an endpoint during a removal process of a material from a microelectronics substrate by detecting luminescence signals.

### BACKGROUND

In the fabrication of microelectronic components, it is well known that various devices are formed in dielectric layers located over a base substrate, such as silicon. These devices are conventionally formed by first lithographically forming openings in the dielectric layers and then depositing a conductive metal, such as aluminum, tungsten or copper within the openings. The metal is typically deposited in such a way as to leave an excess amount on top of the dielectric layer, which is sometimes referred to as “overburden.” This overburden metal must be removed to properly expose the underlying metal filled interconnects or contact openings.

Typically this overburden is removed by a well known process called chemical mechanical planarization (CMP). CMP is also used to planarize or flatten surface topography. It is desirable that all layers have a smooth surface topography, since it is difficult to lithographically image and pattern layers applied to non-uniform surfaces. Moreover, the non-planarity that occurs at one level can be reflected in layers deposited over it, which potentially propagates and amplifies the non-planarity at each successive level. Typically, a given microelectronics wafer may be planarized several times during the fabrication process. Thus, planarization is very important in achieving a high quality microelectronics device.

The point at which to cease the CMP process, which is referred to as the endpoint, is also of great concern within the microelectronics fabrication industry. If the overburden is not sufficiently removed, the circuit will be shorted and fail. On the other hand, if too much over-polish of the dielectric layer and the interconnect or contact structures occurs, the electrical properties of the integrated circuit can be detrimentally affected. For example, sheet resistance or parasitic capacitance may increase, thereby affecting device speed.

To overcome these problems, the industry has developed endpoint detection methods. One such method is an optical method that involves reflecting light off of the polished side of a microelectronics wafer during the polishing process. In many of these optical processes, a beam of light that has a given wavelength is projected through a window formed through the underside of a polishing platen. As the wafer rotates around, the light is projected through the window and reflected off the polished surface of the wafer at the same given wavelength. These optical methods depend on detecting a change in the intensity of the light that is reflected off the polished surface of the wafer. Often such light is also refracted by transparent films on the surface of the wafer and reflected back, causing interference patterns which enables estimation of remaining film thickness. When polishing metal overburden, the metal is highly reflective and has a much stronger reflective intensity than does the underlying dielectric material. Thus, when the metal is removed, ideally, the reflective intensity changes, thereby, indicating an endpoint, i.e. removal, of the overburden of metal.

Unfortunately, however, these optical methods suffer from certain drawbacks. For example, the optical methods can produce sporadic results, usually due to pattern density and orientation, or due to the interference mentioned above, and thus, is not always consistent in indicating the endpoint or total removal of the metal. In addition, a false intensity change may also occur from a polished region where the metal removal has progressed to such an extent that the metal becomes transparently thin. In such instances, an intensity change may be detected even though the metal still remains. Also, in those instances where the underlying material is similar to the material overlying it, it can be very difficult to detect a change in reflective intensity.

Another method for endpoint detection involves measurement of change in Eddy Current during metal removal. The level of Eddy Current is proportional to metal thickness. The Eddy current signal will become very small nearest to endpoint, impacting its usefulness; current detected in the remaining desired metal overshadows the loss from the newly cleared area.

Another common endpoint system involves monitoring of motor current. Changes in current occur when the friction changes as one film begins to clear and the underlying film is exposed to the polishing process. Partial metal removal makes it difficult to trigger this endpoint system, causing over-polish.

Accordingly, what is needed in the art is a method and system for more accurately detecting an endpoint of a removal of material from a microelectronics substrate.

### SUMMARY OF INVENTION

To overcome the deficiencies in the prior art, the present invention, in one embodiment, provides a method of detecting an endpoint of the removal of a material from a microelectronics substrate. This embodiment comprises removing at least a portion of an overlying material located over a luminescent layer. The luminescent layer is located over a microelectronics substrate. Luminescent radiation is used to determine an endpoint of the removal of the overlying material.

In another embodiment, the present invention comprises a method of fabricating an integrated circuit. This method comprises forming transistors over a microelectronics substrate, depositing a luminescent layer over the transistors, and forming interconnects in the luminescent layer to electrically connect the transistors to form an operative integrated circuit. The formation of the interconnects comprises depositing an overlying material over the luminescent layer, removing at least a portion of the overlying material, and using luminescent radiation to determine an endpoint of the removal of the overlying material.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1A illustrates one embodiment of the method of detecting an endpoint of the removal of a material from a microelectronics device, as provided by the present invention that includes an excitation source for radiating the polishing side of a microelectronics wafer and a luminescence detector for measuring photo emissions from a luminescent material that is exposed during a CMP process;

FIG. 1B illustrates another embodiment similar to that shown in FIG. 1A with the addition of two additional endpoint detection apparatus, which includes a motor electrically coupled to an amp meter for detecting a change in motor current and a light source and reflectivity meter for detecting a change in reflective intensity;

FIG. 2 illustrates a partial sectional view of a partially completed microelectronics device during a removal of an overlying material located over a luminescent material that is located over a microelectronics substrate;

FIG. 3 illustrates a partial sectional view of the microelectronics device of FIG. 2 after the partial removal of the overlying material;

FIG. 4 illustrates a partial sectional view of the partially completed microelectronics device of FIG. 3 after the exposure of the luminescent material to the excitation source;

FIG. 5A illustrates a graph of luminescence spectra of an undoped dielectric material formed from Tetra Ethyl Ortho Silicate (TEOS);

FIG. 5B illustrates a graph of luminescence spectra of fluorosilicate glass (FSG);

FIG. 5C illustrates a graph of luminescence spectra of phosphorus silicate glass (PSG); and

FIG. 6 illustrates an exemplary cross-sectional view of an integrated circuit (IC) incorporating devices constructed according to the principles of the present invention.

### DETAILED DESCRIPTION

The present invention recognizes the benefits associated with using luminescence technique to determine an endpoint of the removal of a material from a microelectronics substrate. Unlike conventional optical reflectance methods, the present invention utilizes the luminescence properties of certain materials that are typically used to manufacture microelectronic devices, such as integrated circuits (ICs). In many instances the microelectronic devices are covered by an overlying material, such as metal, that either does not emit luminescence signals at all when excited with the same wavelength used to excite the underlying luminescent material, or emits luminescence at a lower wavelength than the excitation wavelength. Thus, when the overlying material is removed, the underlying layer will generate luminescence when excited at the proper wavelength, thereby indicating an endpoint removal of the overlying material.

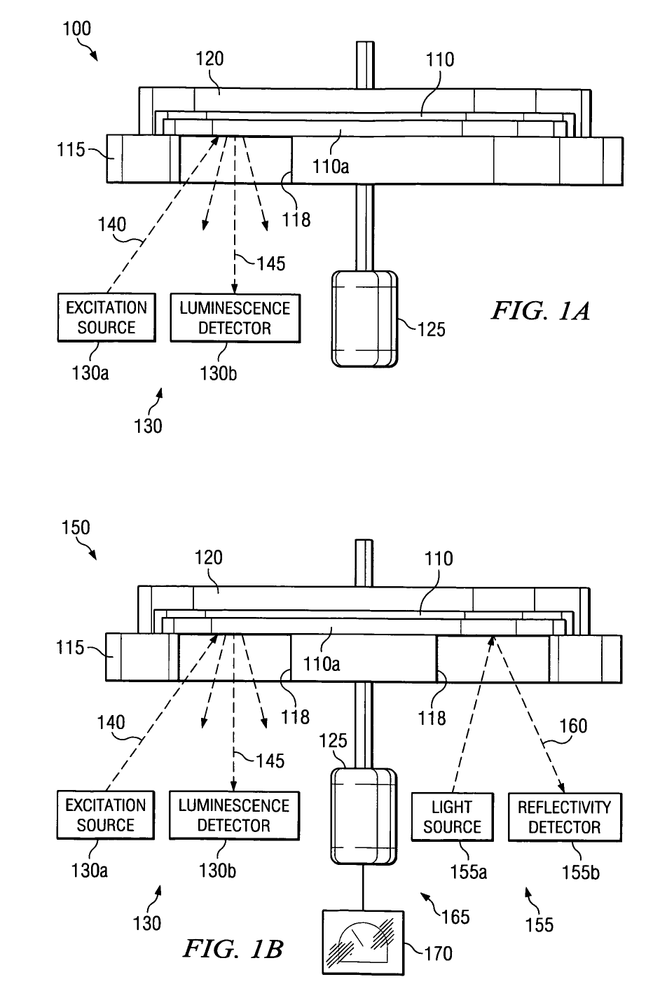

Turning initially to FIG. 1A, there is illustrated a schematic view of one embodiment 100 of detecting an endpoint of the removal of a material from a microelectronics substrate 110. In advantageous applications, the microelectronics substrate 110 is a wafer that is placed on a polishing platen 115, which also includes a window 118, through which a light beam can be projected onto the surface of the microelectronic substrate 110. It should be understood that while only one window is illustrated, in other embodiments, the polishing platen 115 may include a number of windows arranged in various configurations to improve data reliability. In this embodiment, a conventional polishing slurry mixture is applied to the polishing platen 115 and used to remove the overburden metal deposited on the microelectronics substrate 110. A carrier head 120 is used to hold the microelectronics substrate 110 against the polishing platen 115 as it is being polished. A motor 125 is used to rotate the polishing platen 115 in the desired direction and at the desired speed. Such polishing systems are well known to those who are skilled in the art.

Also illustrated in this embodiment is a luminescence system 130 that comprises an excitation source 130a and a luminescence detector 130b. In an exemplary embodiment, the excitation source 130a can be a laser or lamp that is capable of generating light in the ultra-violet range that has a wavelength of about 400 nm or less. The laser that is used and its propagation wavelength, however, will depend on the type of luminescent material 110a that is present. For example, in some instances the luminescent material 110a may require a wavelength of 600 nm to become excited. In such cases, the excitation source 130a may be selected to produce light having a wavelength in that range. Thus, the present invention is not limited to any particular wavelength or material. In an alternative embodiment, a multi-wavelength “lamp” can also be used. As explained below, the luminescence detector 130b is preferably capable of detecting photon emissions at a single wavelength or generating a luminescence spectrum based on the light emanating from the luminescent material 130b.

As the microelectronics substrate 110 is rotated over the window 118, the excitation source 130a projects radiation 140 through the window 118, which propagates at a given wavelength and onto a luminescent material 110a. A few examples of the luminescent material 110a are discussed below. However, it should be understood at the outset that there is not a limitation on the type of material that can be used as long as that material is capable of generating a luminescence signal at some specified wavelength and emits radiation at a wavelength that is different from that of the overlying material. If the luminescent material 110a is exposed, as the microelectronics substrate 110 passes over the window 118, the luminescent material 110a will become excited due to being radiated at that the given wavelength. The luminescence emissions are indicated by the arrows 145. In most cases, the emissions of the luminescence 145 will propagate at a different wavelength, usually greater, than the wavelength at which the radiation 140 propagates because it typically will have less energy than that associated with the radiation emitted from the excitation source 130a. For example, if the radiation 140 propagates at 400 nm, the luminescent material 110a may emit a luminescence signal at 450 nm. It should be understood, however, that these stated wavelengths and the differences between them may vary from one embodiment to another.

The luminescence 145 is detected by the luminescence detector 130b. Preferably, the luminescence detector 130b is configured to detect photons that are emitted from the luminescent material 110a. This detection can be done either by determining luminescence intensity emitted from the luminescent material 110a at peak intensity or by comparing a detected luminescence spectrum to a standard spectrum of the particular luminescent material 110a, as discussed below.

Turning now to FIG. 1B, there is illustrated another embodiment 150, as provided by the present invention. Embodiment 150 further comprises a conventional optical system 155 for detecting a change in reflective intensity that can be used with the luminescence system 130. The optical system 155 preferably includes a light source 155a, such as a laser operating in the visible range (450 nm to 675 nm), and a reflectivity detector 155b for detecting a change in the intensity of a reflected signal 160 that is reflected off an exposed material. As is well understood and unlike the luminescence system 130, the optical system 155 measures only an intensity of reflected light and does not measure or detect the level of photon emissions from within the exposed material. Stated otherwise, if a particular wavelength is projected onto the surface of the exposed material, then that same wavelength is reflected from that material. This is in contrast to the present invention where the emanating wavelength is typically different from the wavelength of the excitation. However, the optical system 155, can nevertheless be used with the luminescence system 130 to provide further data to more accurately determine when an endpoint is reached.

In addition to the optical system 155, the embodiment 150 may further comprise a conventional friction detection (FD) system 165 that is capable of detecting a change in the amount of friction during the polishing process. This FD system 165 may be used along with the optical system 155 and the luminescence system 130, or it alone may be used with the luminescence system 130 to also provide further data to more accurately determine when an endpoint is reached. In one embodiment, the FD system 165 comprises the motor 125 and an amp meter 170 that is capable of measuring a change in motor current. The FD system 165 relies on the change in the motor current that occurs as a result of encountering either more or less rotational friction associated with polishing different materials.

In one case, the overlying material may be more difficult to remove than the underlying material. In such cases, more friction will be present during the polishing of that material. However, as that overlying material is removed and the underlying material is encountered, it may be easier to remove, which will produce less friction and cause a change in the motor current that can be detected by the amp meter 170. While the luminescence system 130 alone can be very reliable in detecting polishing endpoints, the optical system 155 and FD system 165 add tools that can provide additional data in determining endpoints.

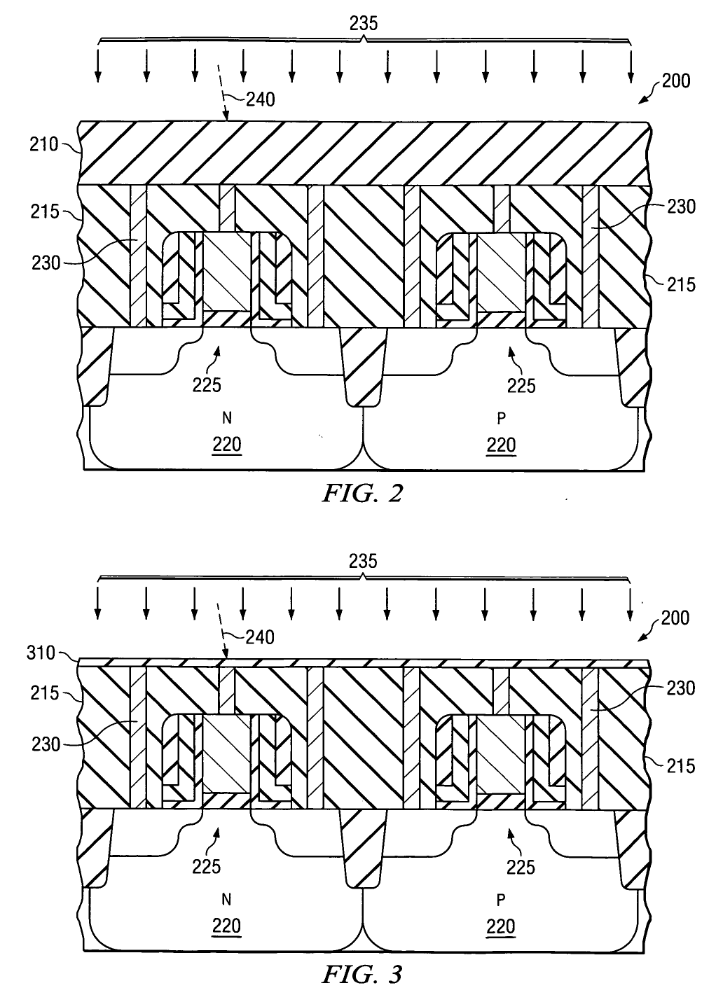

Turning now to FIG. 2, there is illustrated a partial sectional view of a partially completed microelectronics device 200 during a removal of an overlying material 210 that is located over a luminescent material 215. The luminescent material 215 is, in turn, located over a microelectronics substrate 220. The microelectronics device 200 includes transistors 225 located at the device level. The luminescent material 215 overlies the transistors 225 and electrically isolates them and serves as a substrate in which and on which interconnect structures 230 can be formed. The interconnect structures 230 may be of any type typically found in a microelectronics device, such as contact plugs that contact the transistor device level or interlevel vias that are used to electrically connect one level within the microelectronics device 200 to another level of that device. The luminescent material 215, in a preferred embodiment, comprises a dielectric material, such as Undoped Silicate Glass (USG); possibly made from TEOS or silane, Phosphosilicate Glass (PSG), Fluorosilicate Glass (FSG), Borophosphosilicate Glass (BPSG), Organosilicate Glass (OSG), or Silicon Carbide (SiC). It should also be understood that the luminescent material 215 may occur at any level within the microelectronics device 200, and any material that can emit a luminescence signal when excited at a specified wavelength, as mentioned above, may also be used to trigger the endpoint.

The removal of the overlying material 210 is illustrated by arrows 235. The removal may be accomplished by a number of processes known to those skilled in the art. In one example, the removal process may be accomplished by using a CMP process, alternatively, however, the removal may be done by other conventional means. One such example is by conventional wet etch processes and others include dry etch processes, including plasma processes, or reactive ion etching. Since these processes are all conventional, those who are skilled in the art would understand how to employ each of these removal processes.

In an exemplary embodiment, the overlying material 210 is a metal, such as copper, aluminum, tungsten, molybdenum, or alloys thereof, that has been deposited over the luminescent material 215. The overlying material 210 is not limited to any particular material as long as it either does not emit luminescence at all when excited with the same wavelength used to radiate the underlying luminescent material 215, or emits a luminescence signal at a different wavelength than the underlying luminescent material 215. In the embodiment illustrated in FIG. 2, the overlying material 210 is being excited with a light beam 240 from an excitation source, as those discussed above. Preferably, the radiation is photonic in nature and the luminescence that occurs is photoluminescence. Photoluminescence occurs when an excited electron in an excited state returns to the initial state by emission of a photon whose energy gives the difference between the excited state and the initial state energies. The process can be direct or indirect depending on the gap energy of the material being radiated. In exemplary embodiments, the photonic energy propagates at a wavelength of about 400 nm or less. At these wavelengths, the overlying material 210 does not emit luminescence, and thus, there are no emissions that come from the overlying material 210 that the luminescence detector 130b (FIG. 1) can detect. Therefore, it is known at this stage that no endpoint or complete removal of the overlying material 210 has been achieved.

Referring now briefly to FIG. 3, there is illustrated a partial sectional view of the microelectronics device of FIG. 2 after the partial removal of the overlying material 310. While the thickness of the overlying material 310 has been substantially reduced from that seen in FIG. 2, there are still no photon emissions from the overlying material 310 that can be detected by the luminescence detector 130b (FIG. 1). This figure is also illustrative of one advantage provided by the present invention. As mentioned above, conventional optical systems often provide unreliable endpoints in those instances where the overlying material 310 becomes so thin that a change in reflective intensity is detected even though the overlying material 310 has not been completely removed. This is in contrast to the present invention. Here, even though the overlying material 310 is relatively thin, there are no emissions coming from it. As such, the endpoint is not indicated, thereby increasing accuracy in endpoint detection.

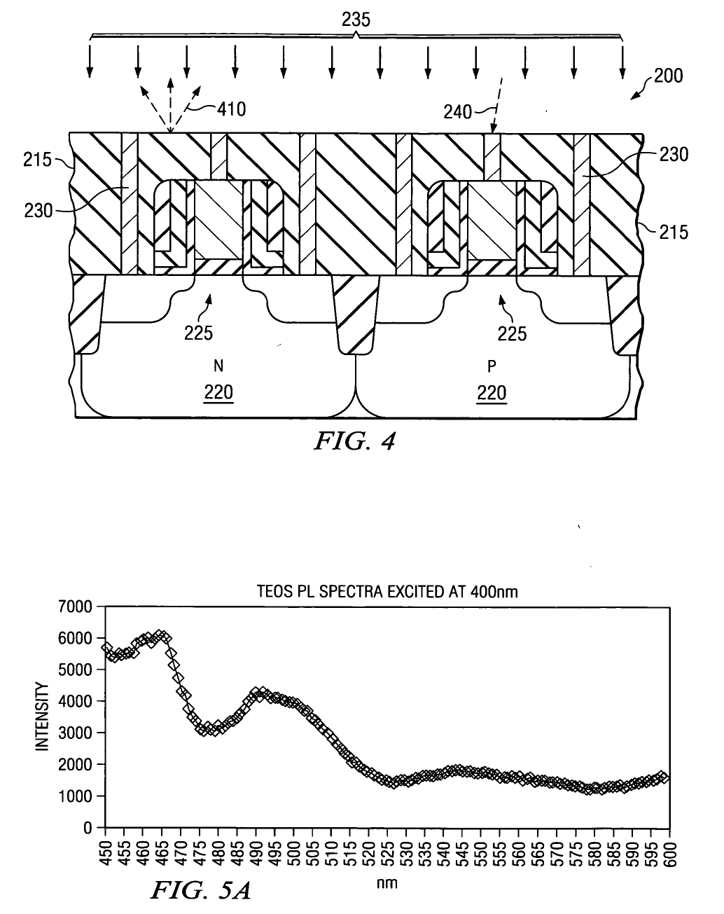

Turning now to FIG. 4, there is illustrated a partial sectional view of the partially completed microelectronics device of FIG. 3 after the removal of the overlying material 310 (FIG. 3) and exposure of the luminescent material 215 to the excitation source 240. Since the overlying material 310 (FIG. 3) has been removed, the excitation source 240 is able to excite the luminescent material 215. The radiation increases the energy levels of certain electrons to the extent that they occupy higher energy levels within the atomic structure. As the electrons return to initial energy levels, they, in turn emit radiation 410. This radiation 410, as explained above, will typically have a wavelength that is greater than the wavelength of the excitation source 410 due to the lower energy level of the emissions. This difference in wavelengths can then be used to detect that the overlying material 310 (FIG. 3) has been removed.

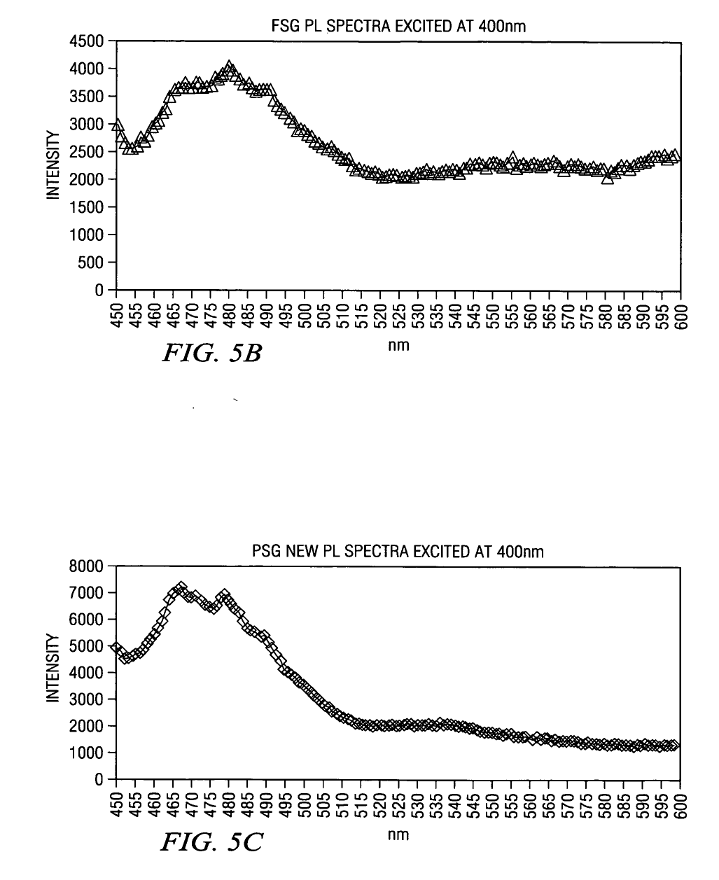

Turning to FIGS. 5A-5C, there are illustrated graphs of luminescence spectra of TEOS, FSG and PSG. Because of their unique electron configuration, each one of these materials exhibits its own identifiable spectrum that is distinguishable from the others. It should be noted that each of these materials were radiated with a laser operating at a wavelength of 400 nm. These materials are often used to form pre-metal dielectric layers over transistors and interlevel dielectric layers in which interconnects can be formed. Typically overlying materials, such as metals used to form runners and interconnects do not exhibit luminescence at excitation wavelengths of 400 nm or less. Therefore, the identifiable spectrum of these materials can be used to determine when an endpoint of the overlying material has been reached by observing the data and resulting spectrum obtained from the luminescence detector. When the overlying material has been removed, the radiation will be able to excite the electrons within the luminescent material and cause it to emit a lower energy radiation and thereby identifying the underlying material.

As seen from the distinguishable spectra of each of these materials, the present invention can be used to determine the endpoint between two different dielectric materials when one is deposited over the other. This also has advantages over conventional processes because of the similarity of the reflectivity of these dielectric materials; it could be very difficult to distinguish between the two. Also conventional frictional systems that depend on change in motor current may be ineffective in determining the endpoint between two similar materials inasmuch as the frictional difference between the two materials may not be sufficient to cause the motor current to change.

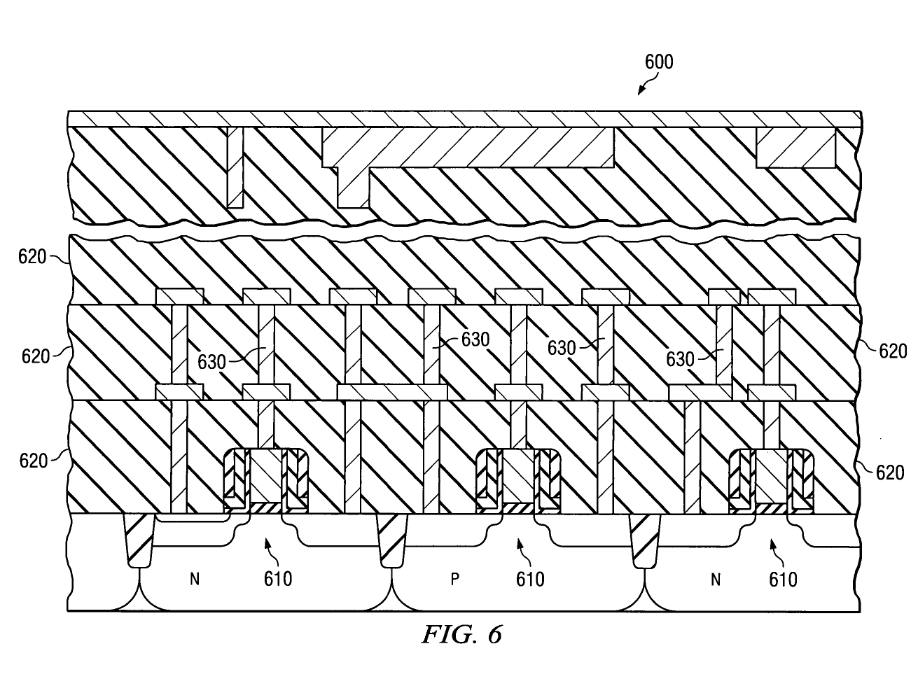

Referring finally to FIG. 6, illustrated is an exemplary cross-sectional view of an integrated circuit (IC) 600 incorporating devices 610 constructed according to the principles of the present invention. The devices 610 may include a wide variety of devices, such as transistors used to form CMOS devices, BiCMOS devices, Bipolar devices, as well as capacitors or other types of devices. The IC 600 may further include passive devices, such as inductors or resistors, or it may also include optical devices or optoelectronic devices. Those skilled in the art are familiar with these various types of devices and their manufacture. In the particular embodiment illustrated in FIG. 6, the devices 610 are transistors over which dielectric layers 620 are located. Additionally, interconnect structures 630 are located within the dielectric layers 620 to interconnect various devices 610, thus, forming an operational integrated circuit 600.

Although the present invention has been described in detail, one who is of ordinary skill in the art should understand that they can make various changes, substitutions, and alterations herein without departing from the scope of the invention.

What is claimed is:

1. A method of detecting an endpoint of the removal of a material from a microelectronics substrate, comprising:
removing at least a portion of an overlying material located over a luminescent layer that is located over a microelectronics substrate; and
using luminescence emission to determine an endpoint of the removal of the overlying material.

2. The method as recited in claim 1, wherein the luminescent layer is a dielectric material.

3. The method as recited in claim 2, wherein the dielectric material is undoped silicate glass, phosphosilicate glass, fluorosilicate glass, borophosphosilicate glass, silicon carbide, or organosilicate glass.

4. The method as recited in claim 1, wherein the overlying material comprises metal.

5. The method as recited in claim 4, wherein the metal is tungsten, aluminum, copper, tantalum, titanium, molybdenum, or combinations thereof.

6. The method as recited in claim 1, wherein using luminescence emission includes using a excitation source having a wavelength of less than or equal to about 400 nm.

7. The method as recited in claim 1, wherein removing at least a portion includes using a chemical mechanical planarization process.

8. The method as recited in claim 7 further comprising detecting a change in a motor current of a motor configured to rotate a polishing platen on which the microelectronics substrate is located or determining a change in reflective intensity by using optical reflectivity.

9. The method as recited in claim 7, wherein using luminescence emission includes projecting the luminescence emission through a window located through the polishing platen.

10. The method as recited in claim 1, wherein removing at least a portion includes using a wet etch process or a plasma etch process.

11. A method of fabricating an integrated circuit, comprising:
forming transistors over a microelectronics substrate;
depositing a luminescent layer over the transistors; and
forming interconnects in the luminescent layer to electrically connect the transistors to form an operative integrated circuit, comprising:
depositing an overlying material over the luminescent layer;
removing at least a portion of the overlying material; and
using luminescence emission to determine an endpoint of the removal of the overlying material.

12. The method as recited in claim 11, wherein the luminescent layer is a dielectric material.

13. The method as recited in claim 12, wherein the dielectric material is undoped silicate glass, phosphosilicate glass, fluorosilicate glass, borophosphosilicate glass, silicon carbide, or organosilicate glass.

14. The method as recited in claim 11, wherein the overlying material comprises metal.

15. The method as recited in claim 14, wherein the metal is tungsten, aluminum, copper, tantalum, titanium, molybdenum, or combinations thereof.

16. The method as recited in claim 11, wherein using luminescence excitation includes using an excitation source having a wavelength of less than or equal to about 400 nm.

17. The method as recited in claim 11, wherein removing at least a portion includes using a chemical mechanical planarization process.

18. The method as recited in claim 17 further comprising detecting a change in a motor current of a motor configured to rotate a polishing platen on which the microelectronics substrate is located or determining a change in reflective intensity by using optical reflectivity.

19. The method as recited in claim 17, wherein using luminescence emission includes projecting the luminescence emission through a plurality of windows located through the polishing platen.

20. The method as recited in claim 11, wherein removing at least a portion includes using a wet etch process or a plasma etch process.
